(19) United States
(12) Patent Application Publication
(10) Pub. No.: US 2025/0169153 A1
(43) Pub. Date: May 22, 2025

(54) ELECTRONIC COMPONENT COMPRISING A GATE STRUCTURE

(71) Applicant: STMicroelectronics International N.V., Geneva (CH)

(72) Inventors: Philippe GALY, Le Touvet (FR); Franck SABATIER, Grenoble (FR); Michel PIORO-LADRIERE, Sherbrooke (QC) (CA)

(73) Assignee: STMicroelectronics International N.V., Geneva (CH)

(21) Appl. No.: 18/947,182

(22) Filed: Nov. 14, 2024

(30) Foreign Application Priority Data
Nov. 16, 2023 (FR) 2312581

(51) Int. Cl. H01L 29/49; H01L 29/78

(52) U.S. Cl. CPC H10D 64/666; H10D 30/60

(57) ABSTRACT

An electronic component includes a gate structure over a semiconductor layer. The gate structure is insulated from the semiconductor layer and includes a layer made of a magnetic material. The electronic component may form a FET transistor, a MOSFET transistor, a SET transistor, a gated diode, a gated MOS structure, or a gated quantum dot.

### PRIORITY CLAIM

This application claims the priority benefit of French Application for Patent No. 2312581, filed on Nov. 16, 2023, the content of which is hereby incorporated by reference in its entirety to the maximum extent allowable by law.

### TECHNICAL FIELD

The present disclosure generally concerns electronic components, and more particularly electronic components comprising a gate structure, for example Metal Oxide Semiconductor (MOS) type electronic components comprising a gate structure on a semiconductor.

For example, the concerned electronic components may be a Field Effect Transistor (FET), a Metal Oxide Field Effect Transistor (MOSFET), a Single Electron Transistor (SET), a gated diode, a MOS structure, and/or gated quantum dots.

### BACKGROUND

Among electronic components comprising a gate structure, MOSFET transistors are known, which are field-effect transistors (FETs) having a gate structure comprising a layer of insulator referred to as a gate insulator which enables to insulate the rest of the gate structure from a semiconductor layer having drain, source, and channel regions of the MOSFET formed therein.

Various MOSFET designs, and in particular a plurality of gate structures, have already been provided.

It would be desirable to at least partly overcome certain disadvantages of known MOSFETs, more generally of electronic components comprising a gate structure. In particular, in certain applications, it may be advantageous to provide the gate structure with other functions.

### SUMMARY

An embodiment provides an electronic component comprising a gate structure on a semiconductor layer, the gate structure including a magnetic material.

According to an embodiment, the gate structure comprises a first layer made of the magnetic material.

According to an embodiment, the gate structure comprises a second layer made of polysilicon, for example in contact with the first layer.

According to an embodiment, the gate structure comprises a third layer made of metal, for example made of titanium nitride, wherein the third layer is between the gate insulator layer and the first layer.

According to an embodiment, the gate structure comprises a gate insulator layer configured to insulate said gate structure from the semiconductor layer, for example in contact with said semiconductor layer.

According to an embodiment, the gate insulator layer is on a first surface of the gate structure in contact with the semiconductor layer, and the gate structure comprises an electrical contact layer, for example made of silicide, on a second surface opposite the first surface.

According to an embodiment, the magnetic material comprises at least one among: cobalt, a cobalt-based material, nickel, or a nickel-based material.

According to an embodiment, the electronic component is a FET transistor, a MOSFET transistor, a SET transistor, a gated diode, a gated MOS structure, or a gated quantum dot.

An embodiment provides an electronic device comprising a semiconductor layer and at least one electronic component such as described hereabove, the at least one electronic component being inside and on top of the semiconductor layer.

According to an embodiment, the at least one electronic component is a MOS structure, the electronic device comprising an inductor integrated on the MOS structure.

According to an embodiment, the gate structure of the MOS structure comprises a plurality of combs coupled to a central pin, each comb and the pin including the magnetic material.

According to an embodiment, the electronic device is a quantum device comprising a first electronic component among the at least one electronic component, said first electronic component being a quantum dot forming a spin qubit confinement region.

According to an embodiment, the electronic device comprises a second electronic component among the at least one electronic component, said second electronic component being of the type of the MOSFET transistor forming an injector of charge carriers towards the quantum dot.

According to an embodiment, the electronic device further comprises an external magnetic field generator.

According to an embodiment, the semiconductor layer is a silicon layer, for example a surface silicon layer of an SOI-type substrate.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, in a cross-section view, an example of an electronic component being a MOS transistor;

FIG. 2A shows, in a cross-section view, an electronic component according to an embodiment;

FIG. 2B shows, in a cross-section view, a variant of the electronic component of FIG. 2A;

FIG. 3A shows, in a cross-section view, an electronic component according to another embodiment;

FIG. 3B shows, in a cross-section view, a variant of the electronic component of FIG. 3A;

FIG. 4A shows, in a top view, an electronic device comprising an electronic component according to another embodiment;

FIG. 4B shows, in a cross-section view, the electronic device of FIG. 4A;

FIG. 5A shows, in a top view, an electronic device comprising an electronic component according to another embodiment;

FIG. 5B shows, in a cross-section view, a detail of the electronic device of FIG. 5A;

FIG. 6A shows curves of the inductance L of various inductors on a MOS structure according to frequency; and

FIG. 6B shows curves of the quality factor Q of various inductors on a MOS structure according to frequency;

FIG. 7 shows, in a 3D view, a variant of the electronic device of FIG. 5A; and

FIG. 8A, FIG. 8B, and FIG. 8C show curves respectively of the inductance, of the resistance, and of the quality factor of the inductor in the electronic device of FIG. 7 according to frequency.

### DETAILED DESCRIPTION

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail. In particular, the steps of the method of manufacturing the electronic components and devices have not been described, since they can be carried out with usual methods of microelectronics. Similarly, not all the details of the electronic components and devices been described. Further, not all the possible applications of the described electronic components and devices have been detailed.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

In the following description, a length corresponds to a dimension in a first lateral direction of the electronic component, which corresponds to the X direction indicated in the drawings, a width corresponds to a dimension in a second lateral direction of the electronic component, orthogonal to the first direction, which corresponds to the Y direction indicated in the drawings, and a thickness or a depth corresponds to a dimension in a direction perpendicular to the first and second directions, which corresponds to the vertical Z direction indicated in the drawings. In certain electronic components, the length may correspond to a channel length between a drain region and a source region of a MOSFET transistor.

In the following description, in order to lighten it, a MOSFET transistor may be referred to as a MOS transistor, or even as a transistor.

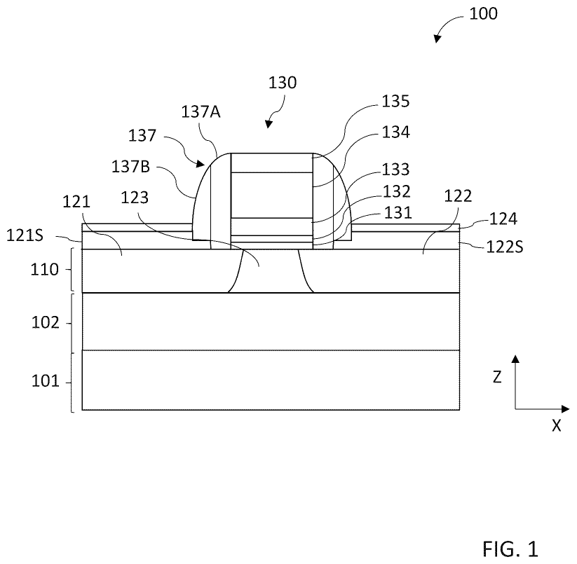

FIG. 1 shows, in a cross-section view, an example of an electronic component 100 being a MOS transistor.

MOS transistor 100 is formed inside and on top of a semiconductor layer 110.

Semiconductor layer 110 is positioned above, preferably in contact with, a buried insulating layer 102 (“BOX” referring to a buried oxide), this buried insulating layer being itself above, preferably in contact with, a substrate 101. Layers 101, 102, 110 correspond, for example, to a substrate of Silicon On Insulator (SOI) type.

Semiconductor layer 110 is, for example, made of silicon, for example of single-crystal silicon. Buried insulating layer 102 is, for example, made of silicon dioxide (SiO₂). Substrate 101 is, for example, made of silicon.

Transistor 100 comprises a drain region 121 and a source region 122 at least partially located in semiconductor layer 110 and very heavily N doped (for an NMOS) or P doped (for a PMOS), and a channel region 123 being formed between the drain region and the source region.

The drain and source regions may comprise raised drain 121S and raised source 122S portions, generally formed by epitaxial growth, as shown in the example of FIG. 1. This enables to increase the thickness of the drain and source regions with respect to the thickness of silicon layer 110, which may be very thin. This may, for example, be the case in a transistor technology of fully-depleted silicon on insulator (FD-SOI) type. In a transistor of FD-SOI type, silicon layer 110 typically has a thickness in the range from a few nanometers to about fifteen nanometers, for example from 5 to 15 nm, and buried insulating layer 102 typically has a thickness in the range from a few nanometers to tens of nanometers, for example from 10 to 50 nm.

Extension regions, having an N (for an NMOS) or P (for a PMOS) doping somewhat lighter than the doping of the drain and source regions (referred to as lightly doped drain (LDD) doping), are generally formed at each junction between the channel region and the source and drain regions, for example to limit the lateral electric field in the MOS transistor.

MOS transistor 100 further comprises a gate structure 130 located above channel region 123.

Gate structure 130 comprises an insulating layer 131, referred to as a gate insulator, which insulates it from channel region 123, for example a layer made of silicon dioxide (SiO₂), and on the gate insulator: a metal layer 133 (optional), for example made of titanium nitride (TiN), TiN being a so-called “mid-gap” material for example enabling to have balanced threshold voltages between an NMOS and a PMOS; a polysilicon layer 134 on layer 133; and, generally, a conductive contact layer 135, typically a silicide layer, on layer 134, enabling to decrease the access resistance.

An insulating film 132 made of a material having a high dielectric constant k (high k) as compared with that of silicon dioxide, for example a hafnium oxide film (HfO₂), may be positioned on insulating layer 131.

Other gate structures and/or other stacks of layer are possible, according to the targeted application and/or performance, for example. Thus, another possible gate structure comprises a polysilicon layer on a gate insulator, generally with a contact layer, for example made of silicide, on the polysilicon layer.

Insulating spacers 137 are formed on either side of gate structure 130, on portions of semiconductor layer 110 which are not covered by this gate structure, and on the side walls (flanks) of gate structure 130. Insulating spacers 137 are, for example, made of a silicon nitride (SiN). An insulating spacer may comprise a plurality of lateral insulating portions, as in the shown example, which shows a first lateral insulating portion 137A (spacer 0) covered by a second lateral insulating portion 137B (spacer 1), where the number of lateral insulating portions may be defined by the MOS transistor manufacturing method.

A function of insulating spacers 137 may be to limit the extension of LDD extension regions under gate structure 130. Insulating spacers 137 may have other functions, which may be made necessary by the MOS transistor manufacturing method. Insulating spacers 137 may be used to decrease a parasitic capacitance of the transistor.

A conductive contact layer 124, typically made of silicide, may be positioned on each of the drain 121 and source 122 regions, for example on the raised portions 121S, 122S of the drain and source regions.

An etch stop layer, for example, made of TiN, topped with a so-called Pre-Metal Dielectric (PMD) region made of a dielectric material which may be silicon dioxide (SiO₂), may be located on transistor 100, and contacts may cross the etch stop layer and the PMD region all the way to the conductive contact layers of transistor 100.

Certain integrated electronic devices on a silicon layer may enable to create, in the silicon layer, one or a plurality of quantum dots, for a use as a confinement region for one or a plurality of quantum bit(s), or spin qubit(s). The structure of a quantum dot is not detailed, being known by those skilled in the art.

Such a quantum dot may be formed by using a technology derived from that of MOS components, for example a technology derived from that of MOS transistors such as the MOS transistor 100 of FIG. 1. The silicon layer in which the quantum dots are formed may correspond to the surface layer, or active layer, of an FD-SOI-type substrate having the MOS component formed inside and on top of it.

The structure of the MOS transistor 100 of FIG. 1 may, for example, be adapted to forming all or part of a quantum dot of a quantum device designed to confine and control a spin qubit. A qubit confinement region may be formed in a portion of silicon layer 110, for example corresponding to channel region 123. Drain and source regions 121, 122 may be drawn away from channel region 123 and replaced with charge carrier reservoirs (charge reservoirs) and/or with injection regions interposed between the confinement region and the charge reservoirs, and gate structure 130 may form a control gate, or front gate, intended to receive an electric potential to control the qubit. Other gate structures may be provided in the quantum device. For example, the qubit may also be controlled by a back gate.

During the operation of the quantum device, the number of charge carriers confined in the quantum dot may be controlled by the Coulomb blockade phenomenon obtained by applying an electric potential to the control gate. For example, the electric potential applied to the control gate may result in lowering the chemical potential of the quantum dot defined in the confinement region, and may thus make the transmission by tunnel effect of a charge carrier originating from the charge reservoirs possible. By the term “charge carrier”, it is generally referred to an electron for an N-doped qubit, but it may also be a hole for a P-doped qubit.

Further, the application of a magnetic field enables to separate in energy the spin states of the qubit confined in the confinement region. For example, it is possible to pass from the low energy state to that of higher energy due to a resonant electromagnetic excitation. When the energy of the electromagnetic excitation is equal to the separation of the spin states, transitions are then possible. One may for this purpose couple the quantum dot with an ESR (Electron Spin Resonance) device, which generates a magnetic field oscillating at the resonance frequency, or an EDSR (Electrical Dipole Spin Resonance) device.

A solution to couple the quantum dot to the ESR or EDSR device may be to position the magnetic field generator element, for example, a current-fed coil, or a magnetic bar, above and/or around the spin qubit confinement region. However, due to this configuration, the field generator element is at a minimum distance from the confinement region, typically a few micrometers away, whereby the magnetic field is attenuated at the location of the qubit.

The inventors provide an electronic component comprising a gate structure enabling to meet the previously-described improvement needs, and to overcome all or part of the disadvantages of the above-described electronic components. In particular, the inventors provide an electronic component comprising a gate structure which enables to integrate a magnetic function, in particular without complicating the method of manufacturing this electronic component.

Embodiments of electronic components comprising a gate structure will be described hereafter. The described embodiments are non-limiting and various variants will become apparent to those skilled in the art based on the indications of the present disclosure.

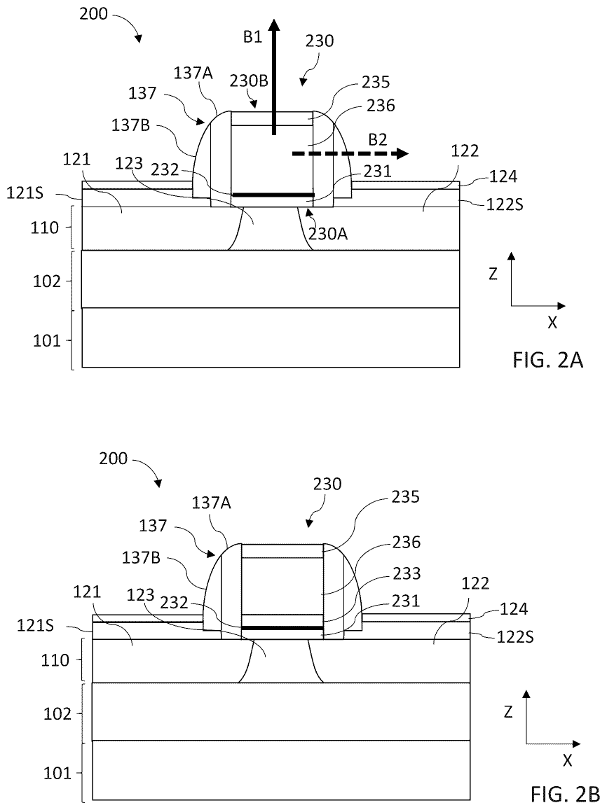

FIG. 2A shows, in a cross-section view, an electronic component 200 according to an embodiment. FIG. 2B shows, in a cross-section view, a variant of the electronic component 200 of FIG. 2A.

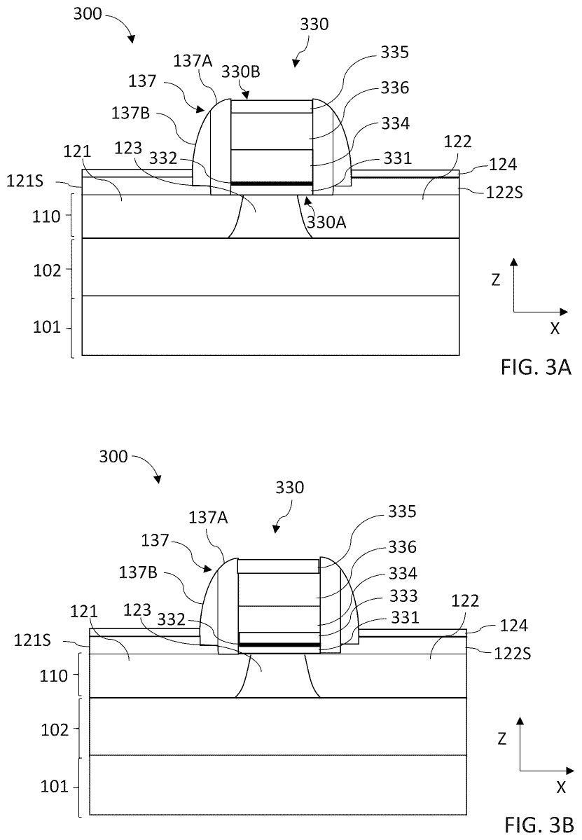

FIG. 3A shows, in a cross-section view, an electronic component 300 according to another embodiment. FIG. 3B shows, in a cross-section view, a variant of the electronic component 300 of FIG. 3A.

The electronic component disclosed in FIGS. 2A, 2B, 3A, 3B is a MOS transistor of SOI type which has characteristics common with the MOS transistor 100 of FIG. 1, but which differs therefrom in that the gate structure comprises a magnetic material. This magnetic material is preferably in the form of a layer of magnetic material. The layer of magnetic material may replace all or part of the polysilicon layer 134 of FIG. 1.

The magnetic material is, for example, cobalt or a cobalt-based material, for example an iron-cobalt alloy (FeCo), nickel, or a nickel-based material.

An advantage of cobalt, or even of nickel, is that this material follows a hysteresis cycle by application of an external magnetic field. An application thereof is that it is possible to modify the orientation and/or the amplitude of the magnetic field generated by the magnetic material (internal magnetic field) by applying to this material an external magnetic field, for example defined by its hysteresis cycle. As shown in FIG. 2A, according to the applied external magnetic field, in a first configuration, the magnetic field B1 generated by the magnetic material (solid vertical arrow) can be oriented in the Z direction, and in a second configuration the magnetic field B2 generated by the magnetic material (dotted horizontal arrow) can be oriented in the X direction.

More widely, an external magnetic field may be applied in addition to the magnetic field generated by the magnetic material in the gate structure (internal magnetic field). For example, the external magnetic field, typically a constant field, may be used for a Zeeman effect, and the internal magnetic field, typically a magnetic gradient, may be used for an electric dipole spin resonance (EDSR) control.

Another advantage of cobalt is that it is compatible with MOS technologies, since it is, for example, already implemented in certain silicide contact layer forming methods.

In the example of FIG. 2A, gate structure 230 comprises an insulating layer 231, called the gate insulator, which insulates it from channel region 123, for example a layer of silicon dioxide (SiO₂), and it further comprises: a layer of magnetic material 236 (first layer) on gate insulator 231; and, generally, a contact layer 235 (electrical contact layer) on the layer of magnetic material 236. The contact layer 235 is an electrically-conductive layer, for example made of tungsten (W) or of titanium silicide (TiSi), for example enabling to decrease the access resistance.

Insulating layer 231 is located on a lower surface 230A (first surface) of gate structure 230, in contact with semiconductor layer 110, while contact layer 235 is located on an upper surface 230B (second surface) of the gate structure opposite to first surface 230A.

One or a plurality of contacts may be provided on contact layer 235, or even directly on the layer of magnetic material 236, for example a contact made of tungsten (W) or of an alloy of titanium and of silicon (TiSi).

The other characteristics of the transistor 200 of FIG. 2A may be similar to those of the transistor 100 of FIG. 1, and the variants described in relation with the transistor 100 of FIG. 1 may also apply to the transistor 200 of FIG. 2A.

For example, in the variant of FIG. 2B, gate structure 230 comprises a metal layer 233 (third layer) between gate insulator 231 and the layer of magnetic material 236. Metal layer 233 may be designated with the term “metal gate”. Metal layer 233 may be made of TiN, TiN being a material of so-called “mid-gap” type, for example enabling to have balanced threshold voltages between an NMOS and a PMOS.

An insulating film 232 of high-k type, for example a hafnium oxide film (HfO₂), may be positioned between gate insulator 231 and layer 236 of magnetic material or metal layer 233.

In the example of FIG. 3A, gate structure 330 comprises an insulating layer 331, called gate insulator, which insulates it from channel region 123, for example a layer of silicon dioxide (SiO₂), and it further comprises: a polysilicon layer 334 (second layer) on gate insulator 331; a layer 336 of magnetic material (first layer) on polysilicon layer 334; and, generally, a contact layer 335 (electric contact layer) on layer 336 of magnetic material: the contact layer is an electrically-conductive layer, for example made of tungsten (W) or of titanium silicide (TiSi), for example enabling to decrease the access resistance.

An advantage of having layers of polysilicon 334 and of magnetic material 336 is to be able to perform an electrical control of the charges in the application to a qubit quantum dot, as well as operations on the qubit due to the magnetic control, and to enable to adjust the magnitude, the location, and the gradient of the magnetic field in channel region 123.

Insulating layer 331 is located on a lower surface 330A (first surface) of gate structure 330, in contact with semiconductor layer 110, while contact layer 335 is located on an upper surface 330B (second surface) of the gate structure opposite to first surface 330A.

One or a plurality of contacts may be provided on contact layer 335, or even directly on layer 336 of magnetic material, for example a contact made of tungsten (W) or of an alloy of titanium and of silicon (TiSi).

The other characteristics of the transistor 300 of FIG. 3A may be similar to those of the transistor 100 of FIG. 1, and the variants described in relation with the transistor 100 of FIG. 1 may also apply to the transistor 300 of FIG. 3A.

For example, in the variant of FIG. 3B, gate structure 330 comprises a metal layer 333 (third layer), or metal gate, between gate insulator 331 and layer 336 of magnetic material. Metal layer 333 may be made of TiN.

An insulating film 332 of high-k type, for example a hafnium oxide film (HfO₂), may be positioned between gate insulator 331 and polysilicon layer 334 or metal layer 333.

Other gate structures and/or stacks of layers are possible, according to the targeted application and/or performance, for example, provided for these structures to comprise a magnetic material, for example a layer of magnetic material. For example, in the example of FIGS. 3A, 3B, the order of polysilicon layer 334 and of layer 336 of magnetic material may be reversed, that is, layer 336 of magnetic material may be on gate insulator 331 and the polysilicon layer 334 on the magnetic material layer 336.

The MOS transistors shown in the description of FIGS. 2A, 2B, 3A, 3B may be N-channel MOS transistors (NMOS), that is, transistors having their source and drain regions N-type doped, for example doped with arsenic or phosphorus atoms, or P-channel MOS transistors (PMOS), that is, transistors having their source and drain regions P-type doped, for example doped with boron atoms.

Each of the electronic components 200, 300 disclosed in FIGS. 2A, 2B, 3A, 3B may be included in an electronic device. The electronic device may comprise one or a plurality of other electronic components formed inside and on top of the same semiconductor layer 110. The electronic components 200, 300 of FIGS. 2A, 2B, 3A, 3B may be combined with one another inside and on top of the same semiconductor layer 110.

According to an example of embodiment, the MOS transistors of FIGS. 2A, 2B, 3A, 3B are transistors of FD-SOI type, for example with a gate dimension of 28 nm (28-nm process node), the different layers then having dimensions related to the 28-nm process node. As an illustration, the semiconductor layer 110 made of Si has a thickness of approximately 7 nm, the drain and source regions 121, 122 with raised portions 121S, 122S have a thickness of approximately 13 nm, the buried insulating layer 102 made of SiO₂ has a thickness of approximately 25 nm, the substrate layer 101 made of Si has a thickness of approximately 100 nm, the layer 236 of magnetic material has a thickness of approximately 24 nm in the example of FIG. 2A, or the layer of magnetic material 336 and of polysilicon 334 each have a thickness of approximately 12 nm in the example of FIG. 3A, and metal layer 233, 333 has a thickness of approximately 6.5 nm in the examples of FIGS. 2B and 3B.

An advantage of having a magnetic material in the gate structure of the electronic component is that this enables to generate a magnetic field from the electronic component, as close as possible to the semiconductor layer, for example as close as possible to channel region 123 in the example shown in FIGS. 2A, 2B, 3A, 3B.

The inventors have determined by simulations, based on a 28-nm process node FD-SOI model with the examples of thicknesses indicated hereabove, that the presence of the magnetic material in the gate structure enables to have a greater magnetic field gradient under, and around, the gate structure, and a smaller spread as it is moved away from the gate structure. In particular, the inventors have determined, by simulations at different levels in the Z direction, that the magnetic field could be particularly significant in the channel region.

The inventors have also determined by simulations that, in the first configuration where magnetic field B1 is oriented in the Z direction, the magnetic field gradient was more elongated in the Z direction than in the X direction, while in the second configuration where magnetic field B2 is oriented in the X direction, the magnetic field gradient was more elongated in the X direction than in the Z direction.

The inventors have also determined that the presence of the magnetic material did not disturb the characteristics of the MOS transistor, for example that the threshold voltage of the transistor was very little impacted. In the application to a qubit quantum dot, the qubit may also be controlled by a back gate (not shown in FIGS. 2A, 2B, 3A, 3B). More generally, the threshold voltage may be adjusted via a voltage on a back gate.

The transistors represented in the description of FIGS. 2A, 2B, 3A, 3B are MOSFET transistors, but the description may extend to other transistors comprising a gate structure, for example to SET transistors, and more generally to any other electronic component comprising a gate structure.

Thus, an electronic component according to an embodiment may be, for example, a FET transistor, a MOSFET transistor, a SET transistor, a gated diode, a gated MOS-type structure (MOS structure), or a gated quantum dot.

MOS transistors according to the embodiments may be manufactured according to techniques known in microelectronics, in particular known MOS transistor manufacturing techniques, using for example the same manufacturing processes. More widely, the electronic components according to the embodiments may be manufactured according to known techniques of microelectronics, in particular known techniques for manufacturing these electronic components, by adapting the gate structure forming steps.

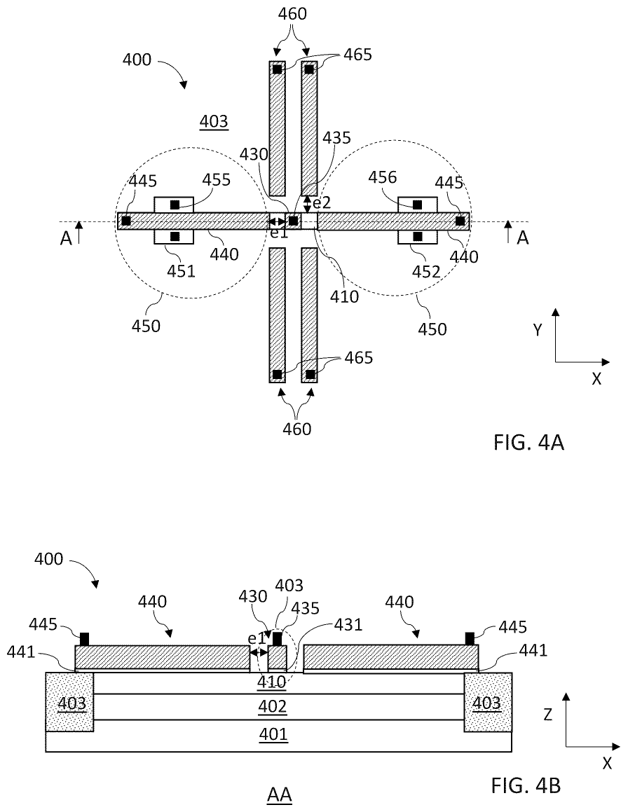

FIG. 4A shows, in a top view, an electronic device 400 comprising an electronic component according to another embodiment. FIG. 4B shows, in a cross-section view (cross-section AA), the electronic device of FIG. 4A.

Electronic device 400 is, for example, configured to form at least one quantum dot, and may be referred to as a quantum device. As an example, when a quantum dot is formed, electronic device 400 may enable to form a spin qubit.

Electronic device 400 comprises a silicon strip 410 which rests on top of, and preferably in contact with, a buried insulating layer 402, for example made of silicon oxide. Buried insulating layer 402 rests on top of, and preferably in contact with, a semiconductor substrate 401, for example made of silicon. The vertical stacking of strip 410, of layer 402, and of substrate 401 may form an SOI structure, strip 410 then corresponding to a portion of the silicon-on-insulator layer.

Strip 410 is laterally delimited by insulating trenches 403, that is, trenches filled with an insulating material such as silicon dioxide, for example trenches of STI (Shallow Trench Insulation) type. Insulating trenches 403 vertically penetrate from an upper surface of device 400 coplanar with the upper surface of strip 410 down to the lower surface of buried insulating layer 402, or even partially penetrates into substrate 401. Thus, strip 410 is delimited by insulating trenches 403 in a first X direction parallel to the length of strip 410 and in a second direction Y perpendicular to the length of strip 410. The first and second X, Y directions are orthogonal to each other and to the vertical direction of the stack.

As an example, when strip 410 corresponds to a portion of a silicon-on-insulator layer, strip 410 is defined in this silicon-on-insulator layer by insulating trenches 403.

Electronic device 400 further comprises a first gate structure 430 (front gate) resting on a central portion of strip 410. The first gate structure 430 may have, in top view, a substantially square shape, although, in other examples, gate structure 430 may have a substantially circular shape and/or be stretched in the longitudinal direction X of strip 410 (first direction). An electrical contact 435 with gate structure 430 may be provided, to allow the application of a voltage to the first gate structure 430.

The first gate structure 430 comprises a gate insulator 431 between strip 410 and the rest of the first gate structure 430.

As an example, the portion of strip 410 located under the first gate structure 430 corresponds to an electronic component which is a quantum dot 403 operating as a confinement region for a spin qubit, and the first gate structure 430 forms a control gate, or front gate, intended to receive an electric potential to control the qubit.

Preferably, the first gate structure 430 comprises a magnetic material, for example cobalt or a cobalt-based material, nickel or a nickel-based material. The magnetic material may be in the form of a layer made of the magnetic material.

In the application where quantum dot 403 forms a confinement region for a spin qubit, a magnetic field may thus be applied as close as possible to the qubit in order to act on the spin, for example to separate in energy the spin states of the qubit confined in the confinement region. The distance between the magnetic field generator element and the qubit is thus decreased as compared with the previously-described solutions where the magnetic field generator element is arranged above and/or around the spin qubit confinement region. According to the embodiments, this distance may thus be a few nanometers instead of a few micrometers.

For example, the ESR technique may be used by applying a radio frequency (RF) signal to front gate 430 to generate an electromagnetic field to be coupled to the charge carrier (hole or electron), or the EDSR technique by applying a DC signal to the front gate 430 and/or to a back gate to displace the charge carrier in a magnetic gradient.

The first gate structure 430 may be similar to any of the gate structures 230, 330 described in relation with FIGS. 2A, 2B, 3A, 3B, for example without the insulating spacers and/or without the silicide regions.

Electronic device 400 further comprises two second gate structures 440 which extend longitudinally in the first X direction on either side of the first gate structure 430 in this first X direction.

Each second gate structure 440 rests on strip 410, while being insulated therefrom by a gate insulator 441, and may also comprise an end resting on trenches 403 as shown in FIG. 4B.

Each second gate structure 440 is separated from the first gate structure 430 by a gap e1. One or a plurality of electrical contacts 445 with each second gate structure 440 may be provided, to allow the application of a voltage to the second gate structure 440.

Electronic device 400 further comprises, under each second gate structure 440, a semiconductor region 451, 452, for example made of silicon, on buried insulating layer 402. Each semiconductor region 451, 452 is, for example, doped with a first conductivity type, for example type N. As an example, each semiconductor region 451, 452 corresponds to a portion of a silicon-on-insulator layer, for example the silicon-on-insulator layer having strip 410 defined therein. As illustrated in FIG. 4A, the first gate structure 430 is between a first semiconductor region 451 and a second semiconductor region 452 in the first X direction. For example, the first semiconductor region 451 forms a drain region, the second semiconductor region 452 forms a source region, the two second gate structures 440 and the first and second semiconductor regions 451, 452 altogether forming an electronic component which is a MOS transistor 450.

The first and second semiconductor regions 451, 452 are exposed. One or a plurality of electrical contacts 455, 456 with each of the first and second semiconductor regions 451, 452 are provided. These electrical contacts 455, 456 enable to apply a voltage to each of the first and second semiconductor regions 451, 452.

As an example, the first semiconductor region 451 is biased, for example to a positive voltage, via electrical contact 455, and the second gate structure 440 which tops the first semiconductor region 451 is also biased via electrical contact 445 to extract a charge carrier potentially generated in the first semiconductor region 451 and to allow it is flowing towards gap e1, in the portion of strip 410 arranged under this second gate structure 440. To cross gap e1 all the way to quantum dot 403, it may be acted on the first gate structure 430, and possibly on one or a plurality of third gate structures 460 described hereafter. It may also be acted on a back gate (not shown in FIGS. 4A and 4B). Each second gate structure 440 can be referred to as a charge carrier injector, or “injector”, or an accumulation gate.

The first and second semiconductor regions 451, 452 are advantageously positioned at a distance from quantum dot 403, for example to avoid noise between these regions and this quantum dot.

For example, each second gate structure 440 comprises a magnetic material, for example cobalt or a cobalt-based material, nickel or a nickel-based material. The magnetic material may be in the form of a layer of magnetic material. This may enable, for example, to precondition the spin of a charge carrier before it is injected into quantum dot 403. Each second gate structure 440 may be similar to any of the gate structures 230, 330 described in relation with FIGS. 2A, 2B, 3A, 3B.

Electronic device 400 further comprises third gate structures 460 arranged in front of gap e1 in the second Y direction, and comprising no portion resting on strip 410. In other words, all or part of the third gate structures 460 rests on insulating trenches 403, at least the portions of the third gate structures 460 positioned above gap e1.

There may be two third gate structures 460 on either side of each gap e1 in the second Y direction, preferably aligned with each other in the second Y direction, as shown in FIG. 4A, or a single third gate structure on one side of each gap e1 in the second Y direction.

The third gate structures 460 are, for example, configured to allow the control of the electrostatic potential in the portion of strip 410 arranged in gap e1 between the first gate structure 430 and each second gate structure 440. For example, when a tunnel barrier is present in space e1, the third gate structures 460 allow the control of this tunnel barrier, a tunnel barrier being, for example, an electrostatic potential barrier which can be crossed by tunnel effect. The potential barriers in gaps e1 correspond to the potential barriers of quantum dot 403 under the first gate structure 430.

One or a plurality of electrical contacts 465 with each third gate structure 460 may be provided, to allow the application of a voltage to each third gate structure 460.

In the example of FIG. 4A, the third gate structures 460 each have, in top view, a substantially rectangular shape, and extend longitudinally in the second Y direction. In another example, not shown, each third gate structure may have, in top view, a substantially square shape.

As an example, a gap e2 separates the portion of strip 410 which is arranged in gap e1 from each third gate structure 460.

According to an example, each third gate structure 460 comprises a magnetic material, for example cobalt or a cobalt-based material, nickel or a nickel-based material. The magnetic material may be in the form of a layer made of the magnetic material. Each third gate structure 460 may then be similar to any of the gate structures 230, 330 described in relation with FIGS. 2A, 2B, 3A, 3B, for example without the insulating spacers.

In the embodiment of FIGS. 4A and 4B, electronic device 400 comprises a single first gate structure 430, and thus a single quantum dot 403. In alternative embodiments, electronic device 400 may comprise at least two first gate structures 430 and thus at least two quantum dots 403, for example next to each other in the first X direction, separated by a non-zero space, for example e1.

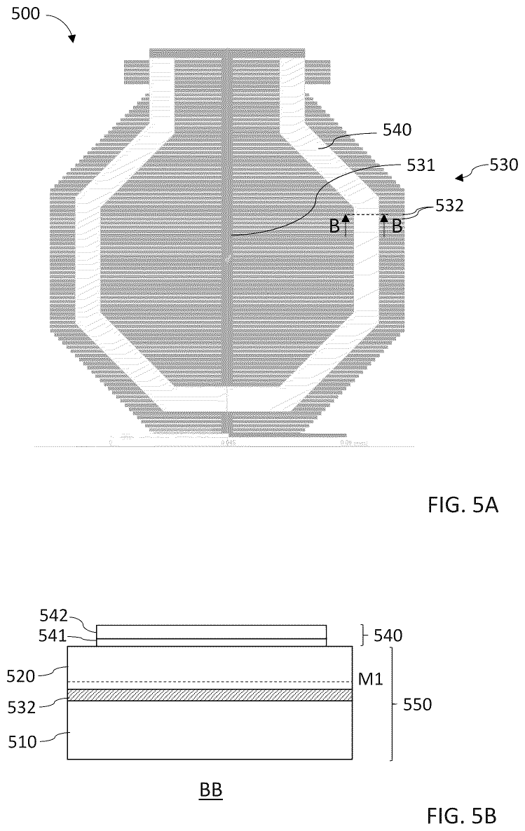

FIG. 5A shows, in a top view, an electronic device 500 comprising an electronic component according to another embodiment. FIG. 5B shows, in a cross-section view (cross-section BB), a detail of the electronic device of FIG. 5A.

The electronic device 500 shown in FIGS. 5A and 5B illustrates an application to the forming of an inductor integrated on a MOS structure forming the electronic component with a gate structure, which may be a structure of SOI type, for example FD-SOI.

Electronic device 500 thus comprises an inductor 540, represented in the form of a single-loop induction coil, positioned above, for example on, a MOS structure 550. Induction coil 540 comprises, for example, a copper layer 541 covered with an aluminum layer 542.

MOS structure 550 comprises a silicon layer 510, which may be a silicon surface layer of a substrate of SOI type, for example FD-SOI. MOS structure 550 comprises, on semiconductor layer 510, a gate structure 530 which appears in the form of a central pin 531 connected to a plurality of combs 532 substantially perpendicular to the central pin, forming a screen as explained hereafter. This gate structure geometry is given as an illustration, and other geometries may be envisaged by those skilled in the art. Between gate structure 530 and inductor 540, MOS structure 550 comprises a dielectric layer 520, which may be a PMD region made of silicon dioxide (SiO₂). Dielectric layer 520 may comprise, or correspond to, an interconnection region (known by those skilled in the art as Back End Of Line (BEOL)), and this interconnection region may comprise a first metallization level, which is the metallization level closest to the substrate, known under denomination “M1”, to which electronic components may be coupled via contacts crossing dielectric layer 520.

Preferably, gate structure 530 comprises a magnetic material, for example cobalt or a cobalt-based material, nickel or a nickel-based material. The magnetic material may be in the form of a layer made of the magnetic material. Gate structure 530 may be similar to any of the gate structures 230, 330 described in relation with FIGS. 2A, 2B, 3A, 3B, for example without the insulating spacers and/or without the silicide regions.

Gate structure 530, including the magnetic material, enables to form a protective screen to decrease interactions between the inductor and the substrate. This protective screen may be grounded.

The inventors have determined that the integration of a magnetic material into gate structure 530 enables to improve certain characteristics of inductor 540, as explained in the following description.

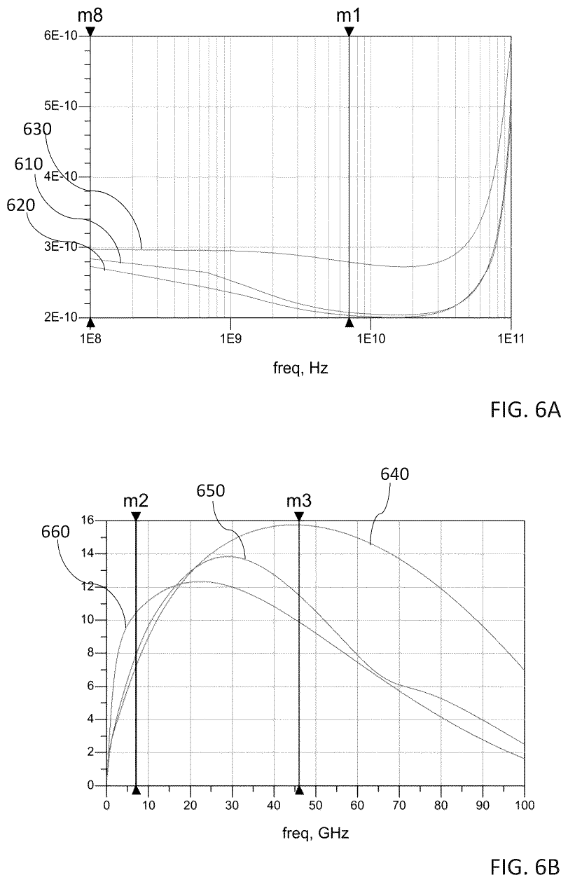

FIG. 6A shows curves showing the inductance L of various inductors on MOS structures according to frequency.

Curve 610 corresponds to a metal screen (with no magnetic material) which, in known fashion, is integrated into the first metallization level M1. Curve 620 corresponds to a metal screen (with no magnetic material) integrated in the silicon layer 510 of FIGS. 5A and 5B. Curve 630 corresponds to the gate structure 530 shown in FIGS. 5A and 5B, with a 1-Tesla (T) magnetic material, forming a metal screen integrated in silicon layer 510.

FIG. 6A shows that the integration of a magnetic material into gate structure 530 under inductor 540 enables to increase the inductance of this inductor. Further, this enables to have a more stable inductance over a wider frequency range.

FIG. 6B shows curves of the quality factor Q of various inductors on MOS structures according to frequency.

Curve 640 corresponds to a metal screen (with no magnetic material) which, in known fashion, is integrated into the first metallization level M1. Curve 650 corresponds to a metal screen (with no magnetic material) integrated in the silicon layer 510 of FIGS. 5A and 5B. Curve 660 corresponds to the gate structure 530 of FIGS. 5A and 5B, with a 1-T magnetic material, forming a metal screen integrated in silicon layer 510.

FIG. 6B shows that the integration of a magnetic material into gate structure 530 under inductor 540 increases the quality factor of this inductor up to a frequency of approximately 15 GHz. This may be advantageous in certain applications, for example in a low-noise amplifier (LNA) of a qubit readout circuit, which typically operates at 7 GHz.

Although a single-loop inductor has been shown in FIGS. 5A and 5B, this embodiment may extend to an induction coil with a plurality of loops such as that described hereabove, or even to any other type of inductor integrated on a MOS structure.

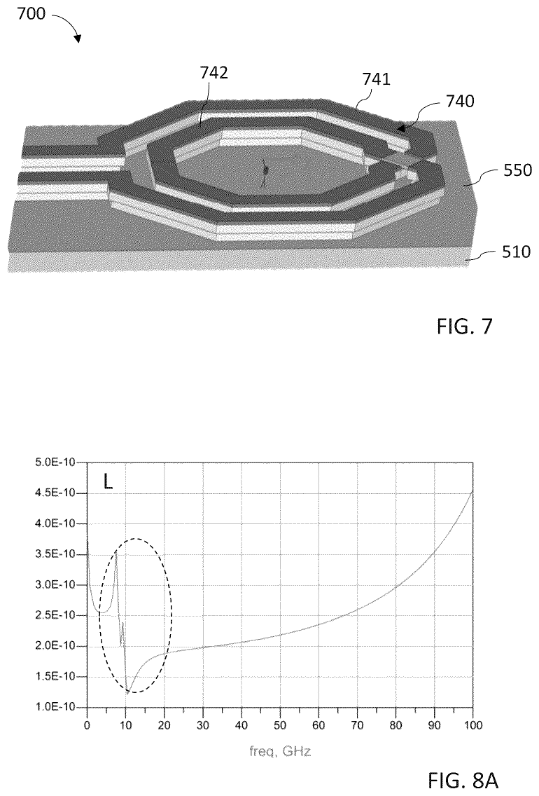

FIG. 7 shows, in a 3D view, a variant of the electronic device of FIG. 5A.

In the example shown in FIG. 7, electronic device 700 comprises an inductor 740 with two concentric loops 741, 742 on a MOS structure 550 such as that described in relation with FIGS. 5A and 5B.

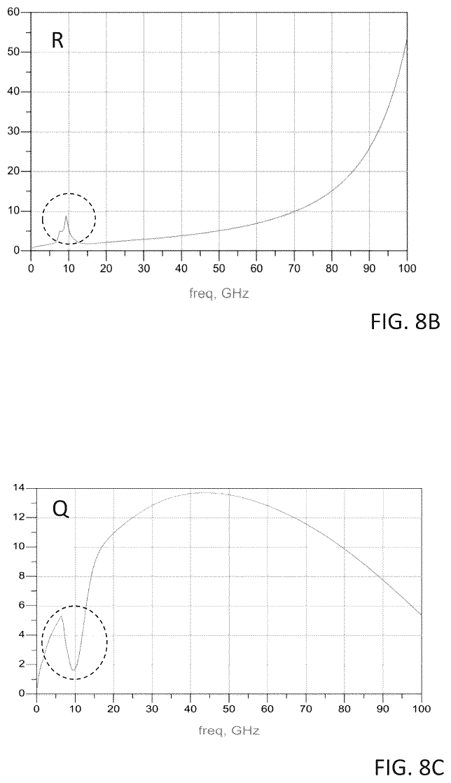

FIG. 8A, FIG. 8B, and FIG. 8C show respective curves of the inductance L, of the resistance R, and of the quality factor Q of the inductor in the electronic device 700 of FIG. 7, according to frequency.

These curves show that the presence of the magnetic material in the gate structure enables to induce on the double-loop inductor a singularity point between approximately 7 and 10 GHz (circled in dotted lines). An application thereof is to form a band rejection filter, or a notch filter.

Various embodiments and variants have been described. Those skilled in the art will understand that certain features of these various embodiments and variants may be combined, and other variants will occur to those skilled in the art.

Finally, the practical implementation of the described embodiments and variants is within the abilities of those skilled in the art based on the functional indications given hereabove.

1. An electronic component, comprising:
a gate structure on a semiconductor layer, wherein the gate structure includes a first layer made of a magnetic material and a second layer made of polysilicon.

2. The electronic component according to claim 1, wherein the second layer is in contact with the first layer.

3. The electronic component according to claim 1, wherein the gate structure further comprises a third layer made of metal.

4. The electronic component according to claim 3, wherein the metal is titanium nitride.

5. The electronic component according to claim 1, wherein the gate structure comprises a gate insulator layer in contact with said semiconductor layer and configured to insulate said gate structure from the semiconductor layer.

6. The electronic component according to claim 5, wherein the gate structure further comprises a third layer made of metal positioned between the gate insulator layer and the first layer.

7. The electronic component according to claim 6, wherein the metal is titanium nitride.

8. The electronic component according to claim 6, wherein the gate insulator layer is on a first surface of the gate structure in contact with the semiconductor layer, and the gate structure further comprises an electrical contact layer made of silicide on a second surface opposite to the first surface.

9. The electronic component according to claim 1, wherein the magnetic material is selected from the group consisting of: cobalt, a cobalt-based material, nickel, or a nickel-based material.

10. The electronic component according to claim 1, wherein the electronic component is a field effect transistor (FET).

11. The electronic component according to claim 1, wherein the electronic component is a single electron transistor (SET).

12. The electronic component according to claim 1, wherein the electronic component is a gated metal oxide semiconductor (MOS) structure.

13. The electronic component according to claim 1, wherein the electronic component is a gated quantum dot.

14. The electronic component according to claim 1, wherein the semiconductor layer is a silicon layer of a silicon on insulator (SOI) type substrate.

15. The electronic component according to claim 1, wherein the gate structure comprises a plurality of combs connected to a central pin, each comb and the central pin including the magnetic material.

16. An electronic device, comprising:
a semiconductor layer;
an electronic component comprising a metal oxide semiconductor (MOS) structure including a gate structure on the semiconductor layer, wherein the gate structure includes a first layer made of a magnetic material and a second layer made of polysilicon; and
an inductor integrated on the MOS structure.

17. The electronic device according to claim 16, wherein the gate structure of the MOS structure comprises a plurality of combs connected to a central pin, each comb and the pin including the magnetic material.

18. The electronic device according to claim 17, wherein the electronic device is a quantum device and the electronic component is a quantum dot forming a spin qubit confinement region.

19. The electronic device according to claim 18, further comprising a field effect transistor (FET) forming an injector of charge carriers towards the quantum dot.

20. The electronic device according to claim 16, further comprising an external magnetic field generator.

21. The electronic according to claim 16, wherein the semiconductor layer is a silicon layer of a silicon on insulator (SOI) type substrate.

22. The electronic device according to claim 16, wherein the gate structure further comprises a third layer made of metal.

23. The electronic device according to claim 22, wherein the metal is titanium nitride.
